(19) United States
(12) Patent Application Publication
(10) Pub. No.: US 2026/0221954 A1
(43) Pub. Date: Jul. 30, 2026

(54) ELECTRONIC CIRCUIT MODULE

(71) Applicant: Murata Manufacturing Co., Ltd., Nagaokakyo-shi (JP)

(72) Inventors: Tetsurou ASHIDA, Nagaokakyo-shi (JP); Tomoya ODA, Nagaokakyo-shi (JP)

(21) Appl. No.: 19/459,130

(22) Filed: Jan. 26, 2026

(30) Foreign Application Priority Data
Jan. 29, 2025 (JP) 2025-013413

(51) Int. Cl. H03H 7/42; H10W 44/20

(52) U.S. Cl. CPC H03H 7/42; H10W 44/209

(57) ABSTRACT

An electronic circuit module includes a main board, a first semiconductor substrate that is disposed above the main board and that has a first side and a second side different from the first side, a second semiconductor substrate that is disposed above the main board and that has a third side and a fourth side different from the third side, a first balun that is disposed in a first region of the main board which is adjacent to the first side of the first semiconductor substrate and which is adjacent to the third side of the second semiconductor substrate, and a second balun that is disposed in a second region of the main board which is adjacent to the second side of the first semiconductor substrate and which is adjacent to the fourth side of the second semiconductor substrate.

### CROSS REFERENCE TO RELATED APPLICATION

This application claims priority from Japanese Patent Application No. 2025-013413, filed on January 29, 2025. The content of these applications are incorporated herein by reference in its entirety.

### BACKGROUND OF THE DISCLOSURE

### 1. Field of the Disclosure

The present disclosure relates to an electronic circuit module.

### 2. Description of the Related Art

Japanese Unexamined Patent Application Publication No. 2021-175053 describes a radio-frequency module. In the radio-frequency module described in Japanese Unexamined Patent Application Publication No. 2021-175053, two baluns are disposed so as to be separate from each other at a distance. Thus, the radio-frequency module described in Japanese Unexamined Patent Application Publication No. 2021-175053 achieves suppression of occurrence of interference between the two baluns.

However, Japanese Unexamined Patent Application Publication No. 2021-175053 does not describe a specific layout of switch ICs and the baluns in detail.

In a radio-frequency module, a switch IC disposed so as to be separate from a balun at a distance makes a wiring line between the switch IC and the balun long. Therefore, it is preferable to dispose the switch IC close to the balun.

In contrast, when two baluns are disposed close to each other, interference between the two baluns occurs.

### BRIEF SUMMARY OF THE DISCLOSURE

The present disclosure is made in view of the circumstances described above, and a possible benefit thereof is to suppress occurrence of interference between baluns with reduction in length of the wiring lines.

According to an aspect of the present disclosure, there is provided an electronic circuit module including: a main board; a first semiconductor substrate that is disposed above the main board and that has a first side and a second side different from the first side; a second semiconductor substrate that is disposed above the main board and that has a third side and a fourth side different from the third side; a first balun that is disposed in a first region of the main board, the first region being adjacent to the first side of the first semiconductor substrate and being adjacent to the third side of the second semiconductor substrate; and a second balun that is disposed in a second region of the main board, the second region being adjacent to the second side of the first semiconductor substrate and being adjacent to the fourth side of the second semiconductor substrate.

According to an aspect of the present disclosure, there is provided an electronic circuit module including: a main board; a first semiconductor substrate that is disposed above the main board; a second semiconductor substrate that is disposed above the main board; a first balun that is disposed in the main board; and a second balun that is disposed in the main board. The first balun is connected to the first semiconductor substrate in a first connection direction. The second balun is connected to the first semiconductor substrate in a second connection direction different from the first connection direction. The first balun is connected to the second semiconductor substrate in a third connection direction. The second balun is connected to the second semiconductor substrate in a fourth connection direction different from the third connection direction.

The present disclosure enables suppression of occurrence of interference between baluns with reduction in length of the wiring lines.

### BRIEF DESCRIPTION OF THE SEVERAL VIEWS OF THE DRAWINGS

FIG. 1 is a diagram illustrating the circuit configuration of a radio-frequency module according to a first embodiment;

FIG. 2 is a plan view of the configuration of an electronic circuit module according to the first embodiment;

FIG. 3 is a diagram illustrating a first wiring layer of a board of the electronic circuit module according to the first embodiment;

FIG. 4 is a diagram illustrating a second wiring layer of the board of the electronic circuit module according to the first embodiment;

FIG. 5 is a diagram illustrating a cross section of the electronic circuit module according to the first embodiment; and

FIG. 6 is a diagram illustrating the configuration of an electronic circuit module according to a second embodiment.

### DETAILED DESCRIPTION OF THE DISCLOSURE

Embodiment of the present disclosure will be described below in detail on the basis of the drawings. The embodiment does not limit the present disclosure. Needless to say, each embodiment is exemplary, and partial replacement or combination of the configurations described in different embodiments may be made. In a second embodiment and its subsequent embodiments, points common to those in a first embodiment will not be described, and only different points will be described. In particular, substantially the same operational effects caused by substantially the same configurations will not be described in each embodiment.

### First Embodiment

### Circuit Configuration

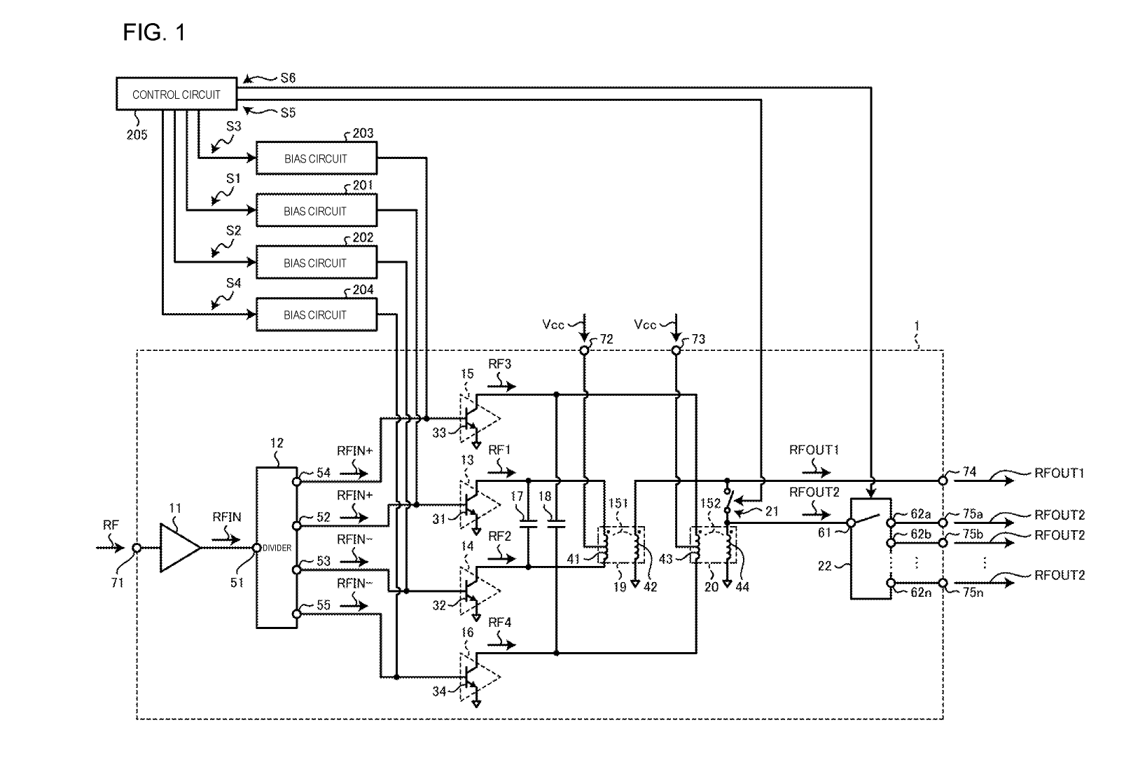

FIG. 1 is a diagram illustrating the circuit configuration of a radio-frequency module according to the first embodiment.

An electronic circuit module 1 may be formed, for example, as a printed circuit board (PCB) by mounting multiple semiconductor substrates (multiple semiconductor devices) on or in a board (for example, a printed wiring board (PWB)).

The electronic circuit module 1 includes an amplifier 11, a divider 12, an amplifier 13, an amplifier 14, an amplifier 15, an amplifier 16, a capacitor 17, a capacitor 18, a balun 19, a balun 20, a switch 21, and a switch 22.

The electronic circuit module 1 has a first mode (hereinafter may be referred to as the "high-power mode") in which all of the amplifiers 13 to 16 operate and in which a relatively large power is outputted. The electronic circuit module 1 has a second mode (hereinafter may be referred to as the "low-power mode") in which only the amplifier 15 and the amplifier 16 perform amplification and the amplifier 13 and the amplifier 14 do not perform amplification and in which a relatively small power is outputted. For example, the output power in the second mode is half of the output power in the first mode. However, the present disclosure is not limited to this.

The amplifier 13 includes a transistor 31. The amplifier 14 includes a transistor 32. The amplifier 15 includes a transistor 33. The amplifier 16 includes a transistor 34.

In the present disclosure, each transistor is a bipolar transistor. However, the present disclosure is not limited to this. For example, the bipolar transistor is a heterojunction bipolar transistor (HBT). However, the present disclosure is not limited to this. For example, the transistor may be a field effect transistor (FET). The transistor may be a multi-finger transistor in which multiple unit transistors are electrically connected in parallel to one another. A unit transistor refers to the minimum configuration of a transistor.

When each transistor is a FET, the source corresponds to the emitter of a bipolar transistor; the gate corresponds to the base of a bipolar transistor; the drain corresponds to the collector of a bipolar transistor.

In the embodiment, the size (the number of fingers) of each of the transistors 31 to 34 is the same. However, the present disclosure is not limited to this. The size of each of the transistors 31 to 34 may be different.

The balun 19 includes a primary winding 41 and a secondary winding 42. The balun 20 includes a primary winding 43 and a secondary winding 44.

The balun 20 corresponds to an example of "first balun" of the present disclosure. The balun 19 corresponds to an example of "second balun" of the present disclosure.

In the embodiment, the inductance value of each of the primary windings 41 to the secondary winding 44 is the same. However, the present disclosure is not limited to this. The inductance value of each of the primary windings 41 to the secondary winding 44 may be different.

The switch 21 corresponds to an example of "first switch" of the present disclosure. The switch 22 corresponds to an example of "second switch" of the present disclosure.

The electronic circuit module 1 receives, at its terminal 71, a single-ended radio-frequency signal RF (unbalanced signal).

The amplifier 11 is electrically connected, at its input terminal, to the terminal 71. The amplifier 11 amplifies the single-ended radio-frequency signal RF received at the input terminal, and outputs, from its output terminal, a single-ended radio-frequency signal RFIN which has been amplified.

The divider 12 is electrically connected, at its input terminal 51, to the output terminal of the amplifier 11. The divider 12 converts the single-ended radio-frequency signal RFIN, which is received at the input terminal 51, to a first-phase radio-frequency signal RFIN+ and a second-phase radio-frequency signal RFIN-, which constitute a differential signal (balanced signal). The divider 12 outputs the first-phase radio-frequency signal RFIN+ from a first output terminal 52 and a third output terminal 54. The divider 12 outputs the second-phase radio-frequency signal RFIN- from a second output terminal 53 and a fourth output terminal 55.

In the embodiment, the first phase is the positive phase (positive polarity); the second phase is the negative phase (negative polarity). However, the present disclosure is not limited to this. The first phase may be the negative phase; the second phase may be the positive phase.

A bias circuit 201 outputs a base bias current to the base of the transistor 31 in accordance with a control signal S1 outputted from a control circuit 205. A bias circuit 202 outputs a base bias current to the base of the transistor 32 in accordance with a control signal S2 outputted from the control circuit 205. A bias circuit 203 outputs a base bias current to the base of the transistor 33 in accordance with a control signal S3 outputted from the control circuit 205. A bias circuit 204 outputs a base bias current to the base of the transistor 34 in accordance with a control signal S4 outputted from the control circuit 205.

The transistor 31 is electrically connected, at its emitter, to a reference potential. For example, the reference potential is the ground potential. However, the present disclosure is not limited to this. The transistor 31 is electrically connected, at its base, to the first output terminal 52 of the divider 12 and the bias circuit 201. The transistor 31 receives, at its base, the first-phase radio-frequency signal RFIN+ from the first output terminal 52 of the divider 12 and the base bias current from the bias circuit 201.

The transistor 31 is electrically connected, at its collector, to a first end of the primary winding 41 of the balun 19. The primary winding 41 is electrically connected, at its intermediate point, to a terminal 72 of the electronic circuit module 1. The primary winding 41 receives, at its intermediate point, a power supply voltage Vcc through the terminal 72. The transistor 31 receives, at its collector, the power supply voltage Vcc through the terminal 72, the intermediate point of the primary winding 41, and the first end of the primary winding 41. The transistor 31 amplifies the first-phase radio-frequency signal RFIN+ received at the base, and outputs a first-phase radio-frequency signal RF1, which has been amplified, from the collector.

The transistor 32 is electrically connected, at its emitter, to a reference potential. The transistor 32 is electrically connected, at its base, to the second output terminal 53 of the divider 12 and the bias circuit 202. The transistor 32 receives, at its base, the second-phase radio-frequency signal RFIN- from the second output terminal 53 of the divider 12 and the base bias current from the bias circuit 202.

The transistor 32 is electrically connected, at its collector, to a second end of the primary winding 41 of the balun 19. The transistor 32 receives, at its collector, the power supply voltage Vcc through the terminal 72, the intermediate point of the primary winding 41, and the second end of the primary winding 41. The transistor 32 amplifies the second-phase radio-frequency signal RFIN- received at the base, and outputs a second-phase radio-frequency signal RF2, which has been amplified, from the collector.

The capacitor 17 is electrically connected, at its first end, to the collector of the transistor 31. The capacitor 17 is electrically connected, at its second end, to the collector of the transistor 32.

The capacitor 17 exerts the impedance matching operation between the collector of the transistor 31 and the collector of the transistor 32.

The primary winding 41 of the balun 19 synthesizes (combines) the first-phase radio-frequency signal RF1, which is outputted from the collector of the transistor 31, with the second-phase radio-frequency signal RF2, which is outputted from the collector of the transistor 32.

The transistor 33 is electrically connected, at its emitter, to a reference potential. The transistor 33 is electrically connected, at its base, to the third output terminal 54 of the divider 12 and the bias circuit 203. The transistor 33 receives, at its base, the first-phase radio-frequency signal RFIN+ from the third output terminal 54 of the divider 12 and the base bias current from the bias circuit 203.

The transistor 33 is electrically connected, at its collector, to a first end of the primary winding 43 of the balun 20. The primary winding 43 is electrically connected, at its intermediate point, to a terminal 73 of the electronic circuit module 1. The primary winding 43 receives, at its intermediate point, a power supply voltage Vcc through the terminal 73. The transistor 33 receives, at its collector, the power supply voltage Vcc through the terminal 73, the intermediate point of the primary winding 43, and the first end of the primary winding 43. The transistor 33 amplifies the first-phase radio-frequency signal RFIN+ received at the base, and outputs a first-phase radio-frequency signal RF3, which has been amplified, from the collector.

The power supply voltage received at the terminal 72 may be the same as or different from that received at the terminal 73.

The transistor 34 is electrically connected, at its emitter, to a reference potential. The transistor 34 is electrically connected, at its base, to the fourth output terminal 55 of the divider 12 and the bias circuit 204. The transistor 34 receives, at its base, the second-phase radio-frequency signal RFIN- from the fourth output terminal 55 of the divider 12 and the base bias current from the bias circuit 204.

The transistor 34 is electrically connected, at its collector, to a second end of the primary winding 43 of the balun 20. The transistor 34 receives, at its collector, the power supply voltage Vcc through the terminal 73, the intermediate point of the primary winding 43, and the second end of the primary winding 43. The transistor 34 amplifies the second-phase radio-frequency signal RFIN- received at the base, and outputs a second-phase radio-frequency signal RF4, which has been amplified, from the collector.

The capacitor 18 is electrically connected, at its first end, to the collector of the transistor 33. The capacitor 18 is electrically connected, at its second end, to the collector of the transistor 34.

The capacitor 18 exerts the impedance matching operation between the collector of the transistor 33 and the collector of the transistor 34.

The primary winding 43 of the balun 20 synthesizes (combines) the first-phase radio-frequency signal RF3, which is outputted from the collector of the transistor 33, with the second-phase radio-frequency signal RF4, which is outputted from the collector of the transistor 34.

The secondary winding 42 of the balun 19 is electrically connected, at its first end, to a terminal 74. The secondary winding 42 is DC grounded or AC grounded at its second end. For example, the secondary winding 42 is electrically connected, at its second end, to a reference potential. However, the present disclosure is not limited to this.

As illustrated by using the dotted line 151, the primary winding 41 is electromagnetically coupled to the secondary winding 42. Therefore, a radio-frequency signal, which occurs from the primary winding 41, propagates to the secondary winding 42 through the electromagnetic field coupling, and is outputted from the terminal 74.

The switch 21 is electrically connected, at its first end, to the first end of the secondary winding 42 of the balun 19 and the terminal 74. The switch 21 is electrically connected, at its second end, to a first end of the secondary winding 44 of the balun 20 and a terminal 61 of the switch 22. The secondary winding 44 of the balun 20 is DC grounded or AC grounded at its second end. For example, the secondary winding 44 is electrically connected, at its second end, to the reference potential. However, the present disclosure is not limited to this.

The switch 21 is controlled to the ON state or the OFF state in accordance with a control signal S5 outputted from the control circuit 205.

As illustrated by using the dotted line 152, the primary winding 43 of the balun 20 is electromagnetically coupled to the secondary winding 44. Therefore, a radio-frequency signal, which occurs from the primary winding 43, propagates to the secondary winding 44 through the electromagnetic field coupling.

Terminals 62a, 62b, …, 62n (n is a natural number) of the switch 22 are electrically connected to terminals 75a, 75b, …, 75n, respectively, of the electronic circuit module 1.

In accordance with a control signal S6 outputted from the control circuit 205, the switch 22 does not electrically connect the terminal 61 to any of the terminals 62a, 62b, …, 62n (in the switch OFF state).

In accordance with the control signal S6, the switch 22 electrically connects the terminal 61 to any of the terminals 62a, 62b, …, 62n (in the switch ON state).

### Operations in First Mode

When the electronic circuit module 1 operates in the first mode, the control circuit 205 performs control so that all the bias circuits 201 to 204 output the base bias currents. Thus, all the amplifiers 13 to 16 perform amplification.

When the electronic circuit module 1 operates in the first mode, the control circuit 205 controls the switch 21 to the ON state.

When the electronic circuit module 1 operates in the first mode, the control circuit 205 controls the switch 22 to the OFF state.

When the switch 21 is in the ON state, the secondary winding 44 of the balun 20 is electrically connected, at its first end, to the first end of the secondary winding 42 of the balun 19 and the terminal 74. That is, the secondary winding 42 is connected in parallel to the secondary winding 44.

Therefore, a radio-frequency output signal RFOUT1, which is outputted from the terminal 74, is a signal obtained by adding the current of the radio-frequency signal outputted from the first end of the secondary winding 42 to the current of the radio-frequency signal outputted from the first end of the secondary winding 44.

### Operations in Second Mode

When the electronic circuit module 1 operates in the second mode, the control circuit 205 performs control so that the bias circuit 203 and the bias circuit 204 output the base bias currents. Thus, the amplifier 15 and the amplifier 16 perform amplification.

When the electronic circuit module 1 operates in the second mode, the control circuit 205 performs control so that the bias circuit 201 and the bias circuit 202 do not output the base bias currents. Thus, the amplifier 13 and the amplifier 14 do not perform amplification.

When the electronic circuit module 1 operates in the second mode, the control circuit 205 controls the switch 21 to the OFF state.

When the electronic circuit module 1 operates in the second mode, the control circuit 205 controls the switch 22 to the ON state. Thus, the terminal 61 is electrically connected to any of the terminals 62a, 62b, …, 62n.

When the switch 21 is in the OFF state, the secondary winding 42 of the balun 19 is electrically disconnected, at its first end, to the first end of the secondary winding 44 of the balun 20 and the terminal 61 of the switch 22.

Therefore, a radio-frequency output signal RFOUT2, which is received at the terminal 61 of the switch 22 and which is outputted from any of the terminals 62a, 62b, …, 62n of the switch 22, is a radio-frequency signal outputted from the first end of the secondary winding 44.

### Effects

(1) The case in which, without the switch 21, the secondary winding 44 of the balun 20 is electrically connected, at its first end, to the first end of the secondary winding 42 of the balun 19 and the terminal 74 will be discussed.

When the electronic circuit module 1 operates in the second mode, the amplifier 13 and the amplifier 14 do not perform amplification.

In this case, when the electronic circuit module 1 is seen from the side of the terminals 75a, 75b, …, 75n (the load side), it is seen as if a parallel resonant circuit which is formed by the capacitor 17 and the primary winding 41 of the balun 19 is electromagnetically coupled to the terminals 75a, 75b, …, 75n through electromagnetic field coupling (see the dotted line 151) between the primary winding 41 and the secondary winding 42.

The resonant frequency of the parallel resonant circuit (the capacitor 17 and the primary winding 41) is almost the same as the frequency of the radio-frequency signals (the first-phase radio-frequency signal RFIN+, the second-phase radio-frequency signal RFIN-, the radio-frequency output signal RFOUT1, and the radio-frequency output signal RFOUT2).

Therefore, in the electronic circuit module 1, a power loss occurs due to the parallel resonant circuit (the capacitor 17 and the primary winding 41), and the efficiency degrades.

In contrast, in the embodiment, when the electronic circuit module 1 operates in the second mode, the control circuit 205 controls the switch 21 to the OFF state.

Thus, the secondary winding 44 is electrically disconnected, at its first end, to the first end of the secondary winding 42.

In this case, when the electronic circuit module 1 is seen from the side of the terminals 75a, 75b, …, 75n (the load side), it is seen as if the parallel resonant circuit (the capacitor 17 and the primary winding 41) is not electromagnetically coupled to the terminals 75a, 75b, …, 75n.

Therefore, the electronic circuit module 1 achieves suppression of occurrence of a power loss caused by the parallel resonant circuit (the capacitor 17 and the primary winding 41), and achieves suppression of occurrence of degradation of the efficiency.

Thus, while suppressing occurrence of a power loss and suppressing occurrence of degradation of the efficiency, the electronic circuit module 1 may implement the first mode for a relatively large output power and the second mode for a relatively small output power.

(2) When the electronic circuit module 1 operates in the first mode, the electronic circuit module 1 outputs the radio-frequency output signal RFOUT1 from the terminal 74.

When the electronic circuit module 1 operates in the second mode, the electronic circuit module 1 outputs the radio-frequency output signal RFOUT2 from any of the terminals 75a, 75b, …, 75n.

Therefore, the electronic circuit module 1 enables the signal path of the radio-frequency output signal RFOUT1 in the case of the first mode to be made different from that of the radio-frequency output signal RFOUT2 in the case of the second mode.

(3) The primary winding 41 of the balun 19 is supplied, at its intermediate point, with the power supply voltage Vcc through the terminal 72. The primary winding 43 of the balun 20 is supplied, at its intermediate point, with the power supply voltage Vcc through the terminal 73. That is, the terminal 72 which supplies the power supply voltage Vcc to the amplifier 13 and the amplifier 14 is separate from the terminal 73 which supplies the power supply voltage Vcc to the amplifier 15 and the amplifier 16.

Therefore, compared with the case in which a single terminal supplies the power supply voltage Vcc to the amplifiers 13 to 16, the current value per power-supply terminal may be made small.

### Configuration of Electronic Circuit Module

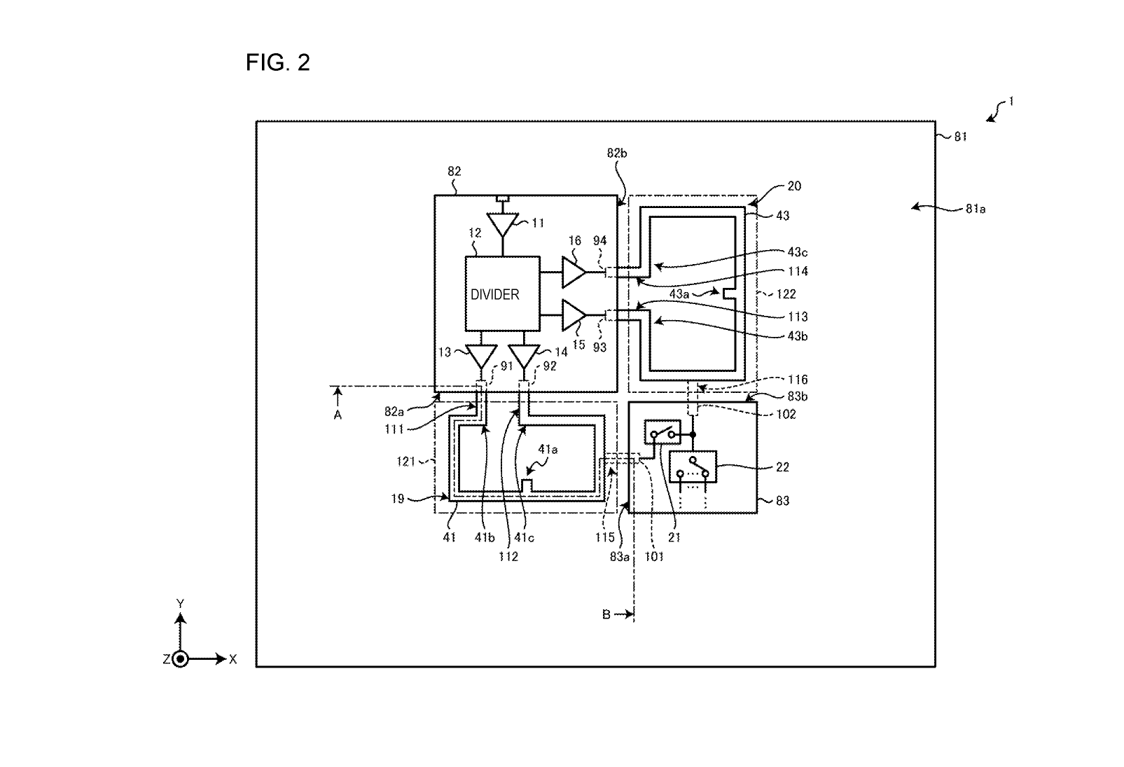

FIG. 2 is a plan view of the configuration of an electronic circuit module according to the first embodiment.

The electronic circuit module 1 includes a board 81, a semiconductor substrate 82, and a semiconductor substrate 83.

The board 81 corresponds to an example of "main board" of the present disclosure. The semiconductor substrate 82 corresponds to an example of "first semiconductor substrate" of the present disclosure. The semiconductor substrate 83 corresponds to an example of "second semiconductor substrate" of the present disclosure.

For example, the board 81 is a printed wiring board (PWB). However, the present disclosure is not limited to this. Each of the semiconductor substrate 82 and the semiconductor substrate 83 may be a bare chip, or may be enclosed in a package.

The semiconductor substrate 82 includes the amplifier 11, the divider 12, the amplifier 13, the amplifier 14, the amplifier 15, and the amplifier 16.

The semiconductor substrate 83 includes the switch 21 and the switch 22.

The board 81 has a first principal surface 81a (a principal surface on the positive Z side) extending in the X-Y plane. The semiconductor substrate 82 and the semiconductor substrate 83 are mounted above the first principal surface 81a of the board 81.

In the embodiment, each of the semiconductor substrate 82 and the semiconductor substrate 83 is quadrilateral (in the embodiment, rectangular) in plan view. However, the present disclosure is not limited to this. Each of the semiconductor substrate 82 and the semiconductor substrate 83 may be shaped like a polygon (a triangle, a pentagon, or the like) in plan view.

In the present disclosure, the plan view refers to viewing the first principal surface 81a in the direction vertical to the first principal surface 81a. In other words, the plan view refers to viewing the first principal surface 81a in the direction from the positive Z side toward the negative Z side.

The board 81 has a region 121 which is adjacent to a side 82a (the side on the negative Y side) of the semiconductor substrate 82 and which is adjacent to a side 83a (the side on the negative X side) of the semiconductor substrate 83. The balun 19 is disposed in the region 121 of the board 81.

The side 82a corresponds to an example of "first side" of the present disclosure. The side 83a corresponds to an example of "third side" of the present disclosure. The region 121 corresponds to an example of "first region" of the present disclosure. The balun 19 corresponds to an example of "first balun" of the present disclosure.

In the embodiment, the balun 19 is formed on a first wiring layer (the farthest wiring layer on the positive Z side) and a second wiring layer (the wiring layer next to the first wiring layer on the negative Z side) of the board 81. However, the present disclosure is not limited to this. The balun 19 may have electronic components mounted on the first principal surface 81a.

The board 81 has a region 122 which is adjacent to a side 82b (the side on the positive X side) of the semiconductor substrate 82 and which is adjacent to a side 83b (the side on the positive Y side) of the semiconductor substrate 83. The balun 20 is disposed in the region 122 of the board 81.

The side 82b corresponds to an example of "second side" of the present disclosure. The side 83b corresponds to an example of "fourth side" of the present disclosure. The region 122 corresponds to an example of "second region" of the present disclosure. The balun 20 corresponds to an example of "second balun" of the present disclosure.

In the embodiment, the balun 20 is formed on the first wiring layer and the second wiring layer of the board 81. However, the present disclosure is not limited to this. The balun 20 may have electronic components mounted on the first principal surface 81a.

The side 82a and the side 82b are adjacent sides. In the embodiment, the side 82a and the side 82b are continuous at an angle of 90°. However, the present disclosure is not limited to this. The side 82a and the side 82b may be continuous at an angle of less than 90° or an angle of greater than 90°.

The side 83a and the side 83b are adjacent sides. In the embodiment, the side 83a and the side 83b are continuous at an angle of 90°. However, the present disclosure is not limited to this. The side 83a and the side 83b may be continuous at an angle of less than 90° or an angle of greater than 90°.

The semiconductor substrate 82 has a terminal 91, a terminal 92, a terminal 93, and a terminal 94 on the surface (the surface on the negative Z side) opposite to the board 81. Each of the terminal 91, the terminal 92, the terminal 93, and the terminal 94 may be a pad.

The output terminal of the amplifier 13 is electrically connected to the terminal 91. The output terminal of the amplifier 14 is electrically connected to the terminal 92. The output terminal of the amplifier 15 is electrically connected to the terminal 93. The output terminal of the amplifier 16 is electrically connected to the terminal 94.

The semiconductor substrate 83 has a terminal 101 and a terminal 102 on the surface (the surface on the negative Z side) opposite to the board 81. Each of the terminal 101 and the terminal 102 may be a pad.

The switch 21 is electrically connected, at its first end, to the terminal 101. The switch 21 is electrically connected, at its second end, to the terminal 102. The switch 22 is electrically connected, at its first end, to the terminal 102.

The balun 19 includes the primary winding 41 formed on the first wiring layer of the board 81 and the secondary winding 42 formed on the second wiring layer of the board 81.

The balun 20 includes the primary winding 43 formed on the first wiring layer of the board 81 and the secondary winding 44 formed on the second wiring layer of the board 81.

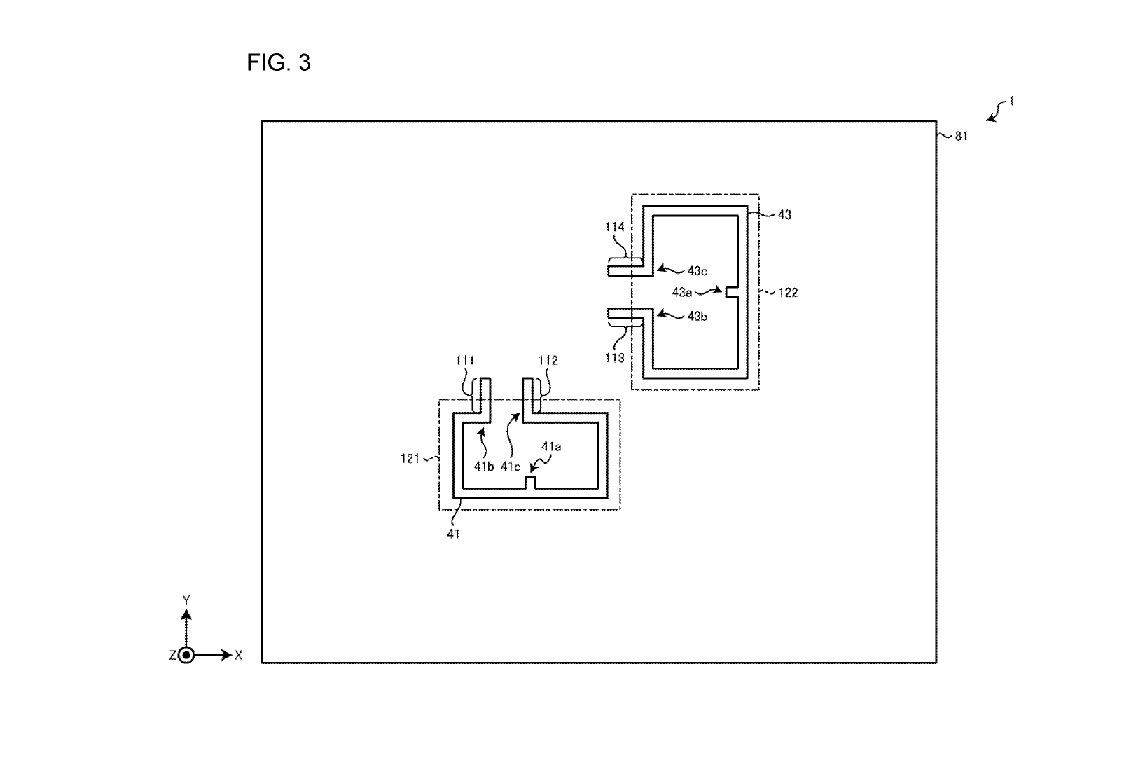

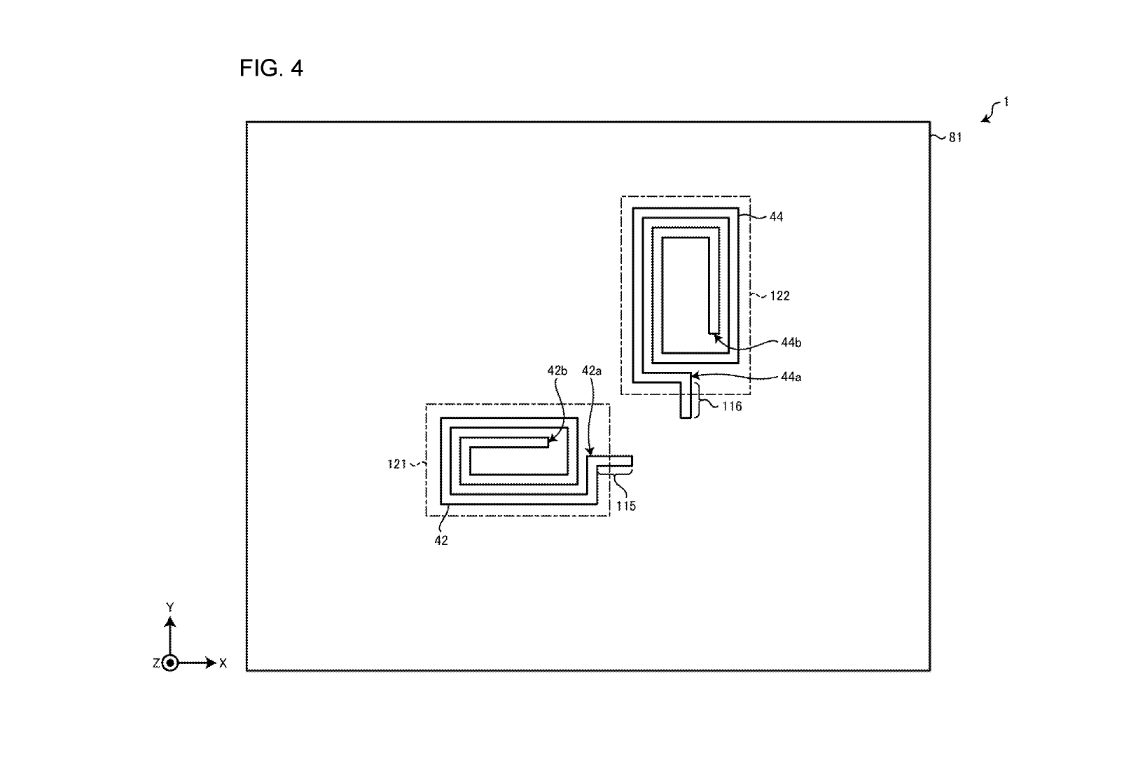

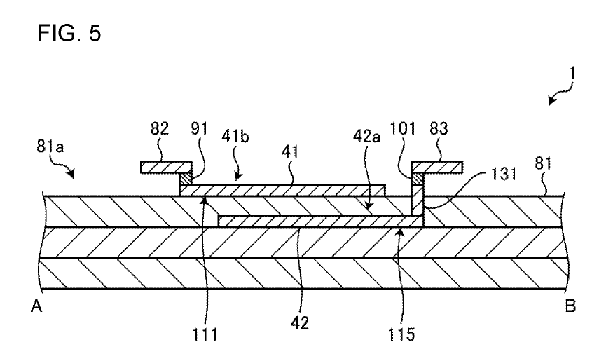

FIG. 3 is a diagram illustrating the first wiring layer of the board of an electronic circuit module according to the first embodiment. FIG. 4 is a diagram illustrating the second wiring layer of the board of an electronic circuit module according to the first embodiment. FIG. 5 is a diagram illustrating a cross section of an electronic circuit module according to the first embodiment.

FIG. 5 is a cross-sectional view of the electronic circuit module 1 along line A-B in FIG. 2.

The primary winding 41 (see FIGS. 2, 3, and 5) of the balun 19 is formed on the first wiring layer (see FIG. 5) of the board 81. The primary winding 41 is wound counterclockwise from a first end 41b (see FIGS. 2, 3, and 5) to the second end 41c (see FIGS. 2 and 3) in plan view. The center portion 41a (see FIGS. 2 and 3) of the primary winding 41 is electrically connected to the power supply voltage Vcc. For example, the center portion 41a is electrically connected through a via to a power-supply wiring line formed on or in a different wiring layer. However, the present disclosure is not limited to this.

The first end 41b (see FIGS. 2, 3, and FIG. 5) of the primary winding 41 is electrically connected to the terminal 91 (see FIGS. 2 and 5) through a wiring line 111 (see FIGS. 2, 3, and FIG. 5) extending along the Y-axis. The second end 41c (see FIGS. 2 and 3) of the primary winding 41 is electrically connected to the terminal 92 (see FIG. 2) through a wiring line 112 (see FIGS. 2 and 3) extending along the Y-axis.

The balun 19 is connected to the semiconductor substrate 82 in the direction from the negative Y side toward the positive Y side.

The direction from the negative Y side toward the positive Y side corresponds to an example of "first connection direction" of the present disclosure.

The secondary winding 42 (see FIGS. 4 and 5) of the balun 19 is formed on the second wiring layer (see FIG. 5) of the board 81. The secondary winding 42 is wound clockwise from a first end 42a (see FIG. 4) to a second end 42b (see FIG. 4) in plan view.

The first end 42a (see FIGS. 4 and 5) of the secondary winding 42 is electrically connected to the terminal 101 (see FIGS. 2 and 5) through a via 131 (see FIG. 5) and a wiring line 115 (see FIGS. 4 and 5) extending along the X-axis. The second end 42b (see FIG. 4) of the secondary winding 42 is electrically connected to the reference potential. For example, the second end 42b is electrically connected through a via to a reference potential wiring line formed on or in a different wiring layer. However, the present disclosure is not limited to this.

The balun 19 is connected to the semiconductor substrate 83 in the direction from the negative X side toward the positive X side.

The direction from the negative X side toward the positive X side corresponds to an example of "third connection direction" of the present disclosure.

The primary winding 43 (see FIGS. 2 and 3) of the balun 20 is formed on the first wiring layer of the board 81. The primary winding 43 is wound counterclockwise from the first end 43b to the second end 43c in plan view. The primary winding 43 has a center portion 43a (see FIGS. 2 and 3) electrically connected to the power supply voltage Vcc. For example, the center portion 43a is electrically connected through a via to a power-supply wiring line formed on or in a different wiring layer. However, the present disclosure is not limited to this.

The first end 43b (see FIGS. 2 and 3) of the primary winding 43 is electrically connected to the terminal 93 (see FIG. 2) through a wiring line 113 (see FIGS. 2 and 3) extending along the X-axis. The second end 43c (see FIGS. 2 and 3) of the primary winding 43 is electrically connected to the terminal 94 (see FIG. 2) through a wiring line 114 (see FIG. 3) extending along the X-axis.

The balun 20 is connected to the semiconductor substrate 82 in the direction from the positive X side toward the negative X side.

The direction from the positive X side toward the negative X side corresponds to an example of "second connection direction" of the present disclosure.

The secondary winding 44 (see FIG. 4) of the balun 20 is formed on the second wiring layer of the board 81. The secondary winding 44 is wound clockwise from a first end 44a to a second end 44b in plan view. The first end 44a (see FIG. 4) of the secondary winding 44 is electrically connected to the terminal 102 (see FIG. 2) through a wiring line 116 (see FIG. 4) extending along the Y-axis. The second end 44b (see FIG. 4) of the secondary winding 44 is electrically connected to the reference potential. For example, the second end 44b is electrically connected through a via to a reference potential wiring line formed on or in a different wiring layer. However, the present disclosure is not limited to this.

The balun 20 is connected to the semiconductor substrate 83 in the direction from the positive Y side toward the negative Y side.

The direction from the positive Y side toward the negative Y side corresponds to an example of "fourth connection direction" of the present disclosure.

In the embodiment, the first connection direction (the direction from the negative Y side toward the positive Y side) and the second connection direction (the direction from the positive X side toward the negative X side) form an angle of 90°. However, the present disclosure is not limited to this. The first connection direction and the second connection direction may form an angle of less than 90° or an angle of greater than 90°.

In the embodiment, the third connection direction (the direction from the negative X side toward the positive X side) and the fourth connection direction (the direction from the positive Y side toward the negative Y side) form an angle of 90°. However, the present disclosure is not limited to this. The third connection direction and the fourth connection direction may form an angle of less than 90° or an angle of greater than 90°.

In the embodiment, the first connection direction (the direction from the negative Y side toward the positive Y side) and the third connection direction (the direction from the negative X side toward the positive X side) form an angle of 90°. However, the present disclosure is not limited to this. The first connection direction and the third connection direction may form an angle of less than 90° or an angle of greater than 90°.

In the embodiment, the second connection direction (the direction from the positive X side toward the negative X side) and the fourth connection direction (the direction from the positive Y side toward the negative Y side) form an angle of 90°. However, the present disclosure is not limited to this. The second connection direction and the fourth connection direction may form an angle of less than 90° or an angle of greater than 90°.

### Effects

The region 121 is not adjacent to the region 122. Therefore, the balun 19 disposed in the region 121 is disposed so as to be separate at a distance from the balun 19 disposed in the region 121.

Thus, the electronic circuit module 1 may suppress occurrence of interference between a signal from the balun 19 and a signal from the balun 20. Therefore, the electronic circuit module 1 achieves improvement of high-frequency characteristics.

The semiconductor substrate 82 is adjacent to the region 121. Therefore, the electronic circuit module 1 may have short lengths of the wiring line 111 and the wiring line 112 between the semiconductor substrate 82 and the primary winding 41 of the balun 19.

Thus, the electronic circuit module 1 may suppress occurrence of a path loss of a radio-frequency signal flowing between the semiconductor substrate 82 and the primary winding 41. Therefore, the electronic circuit module 1 achieves improvement of high-frequency characteristics.

The semiconductor substrate 82 is adjacent to region 122. Therefore, the electronic circuit module 1 may have short lengths of the wiring line 113 and the wiring line 114 between the semiconductor substrate 82 and the primary winding 43 of the balun 20.

Thus, the electronic circuit module 1 may suppress occurrence of a path loss of a radio-frequency signal flowing between the semiconductor substrate 82 and the primary winding 43. Therefore, the electronic circuit module 1 achieves improvement of high-frequency characteristics.

The semiconductor substrate 83 is adjacent to the region 121. Therefore, the electronic circuit module 1 may have a short length of the wiring line 115 between the semiconductor substrate 83 and the secondary winding 42 of the balun 19.

Thus, the electronic circuit module 1 may suppress occurrence of a path loss of a radio-frequency signal flowing between the semiconductor substrate 83 and the secondary winding 42. Therefore, the electronic circuit module 1 achieves improvement of high-frequency characteristics.

The semiconductor substrate 83 is adjacent to the region 122. Therefore, the electronic circuit module 1 may have a short length of the wiring line 116 between the semiconductor substrate 83 and the secondary winding 44 of the balun 20.

Thus, the electronic circuit module 1 may suppress occurrence of a path loss of a radio-frequency signal flowing between the semiconductor substrate 83 and the secondary winding 44. Therefore, the electronic circuit module 1 achieves improvement of high-frequency characteristics.

The semiconductor substrate 82, the semiconductor substrate 83, the region 121, and the region 122 are disposed in a grid without extra space, and are disposed substantially in a rectangular shape as a whole.

Thus, the electronic circuit module 1 may reduce the layout area of the semiconductor substrate 82, the semiconductor substrate 83, the balun 19, and the balun 20. Therefore, the electronic circuit module 1 achieves a reduction in size and a reduction in cost. The electronic circuit module 1 achieves a reduction in size of an electronic device including the electronic circuit module 1, and achieves a reduction in cost of the electronic device.

### Second Embodiment

### Circuit Configuration

The circuit configuration of an electronic circuit module 1A according to the second embodiment is substantially the same as that (see FIG. 1) of the electronic circuit module 1 according to the first embodiment, and will be neither illustrated nor described.

### Configuration of Electronic Circuit Module

Among the components of the electronic circuit module 1A according to the second embodiment, the same components as those of the electronic circuit module 1 according to the first embodiment are designated with the same reference numerals, and will not be described.

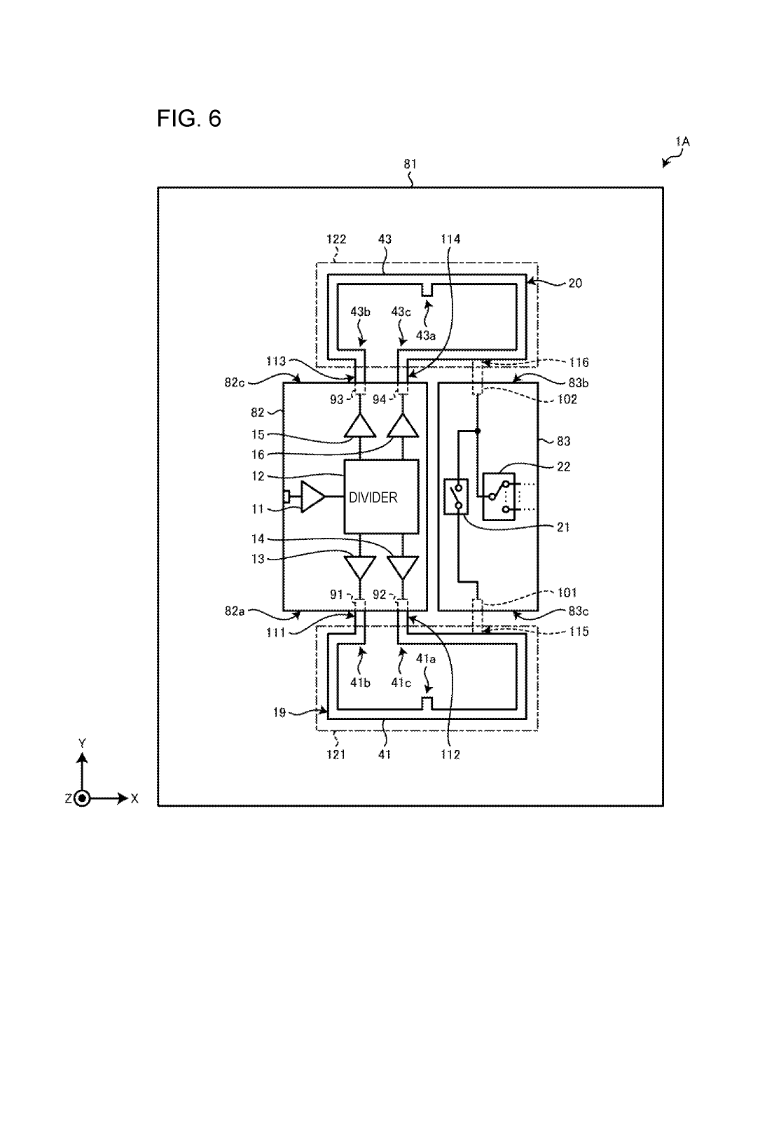

FIG. 6 is a diagram illustrating the configuration of an electronic circuit module according to the second embodiment.

The board 81 has the region 121 which is adjacent to the side 82a (the side on the negative Y side) of the semiconductor substrate 82 and which is adjacent to a side 83c (the side on the negative Y side) of the semiconductor substrate 83. The balun 19 is disposed in the region 121 of the board 81.

The side 82a corresponds to an example of "first side" of the present disclosure. The side 83c corresponds to an example of "third side" of the present disclosure. The region 121 corresponds to an example of "first region" of the present disclosure. The balun 19 corresponds to an example of "first balun" of the present disclosure.

The board 81 has the region 122 which is adjacent to a side 82c (the side on the positive Y side) of the semiconductor substrate 82 and which is adjacent to the side 83b (the side on the positive Y side) of the semiconductor substrate 83. The balun 20 is disposed in the region 122 of the board 81.

The side 82c corresponds to an example of "second side" of the present disclosure. The side 83b corresponds to an example of "fourth side" of the present disclosure. The region 122 corresponds to an example of "second region" of the present disclosure. The balun 20 corresponds to an example of "second balun" of the present disclosure.

The side 82a is opposite to the side 82c. In the embodiment, a single side is present between a first end of the side 82a and a first end of the side 82c. However, the present disclosure is not limited to this. Two or more sides may be present between the first end of the side 82a and the first end of the side 82c. A single side is present between the second end of the side 82a and the second end of the side 82c. However, the present disclosure is not limited to this. Two or more sides may be present between the second end of the side 82a and the second end of the side 82c.

The side 83b is opposite to the side 83c. In the embodiment, a single side is present between a first end of the side 83b and a first end of the side 83c. However, the present disclosure is not limited to this. Two or more sides may be present between the first end of the side 83b and the first end of the side 83c. A single side is present between the second end of the side 83b and the second end of the side 83c. However, the present disclosure is not limited to this. Two or more sides may be present between the second end of the side 83b and the second end of the side 83c.

The first end 41b of the primary winding 41 of the balun 19 is electrically connected to the terminal 91 through the wiring line 111 extending along the Y-axis. The second end 41c of the primary winding 41 is electrically connected to the terminal 92 through the wiring line 112 extending along the Y-axis.

The balun 19 is connected to the semiconductor substrate 82 in the direction from the negative Y side toward the positive Y side.

The direction from the negative Y side toward the positive Y side corresponds to an example of "first connection direction" of the present disclosure.

The secondary winding 42 of the balun 19 is electrically connected, at the first end (not illustrated), to the terminal 101 through the wiring line 115 extending along the Y-axis.

The balun 19 is connected to the semiconductor substrate 83 in the direction from the negative Y side toward the positive Y side.

The direction from the negative Y side toward the positive Y side corresponds to an example of "third connection direction" of the present disclosure.

The first end 43b of the primary winding of the balun 20 is electrically connected to the terminal 93 through the wiring line 113 extending along the Y-axis. The second end 43c of the primary winding 43 is electrically connected to the terminal 94 through the wiring line 114 extending along the Y-axis.

The balun 20 is connected to the semiconductor substrate 82 in the direction from the positive Y side toward the negative Y side.

The direction from the positive Y side toward the negative Y side corresponds to an example of "second connection direction" of the present disclosure.

The secondary winding 44 of the balun 20 is electrically connected, at the first end (not illustrated), to the terminal 102 through the wiring line 116 extending along the Y-axis.

The balun 20 is connected to the semiconductor substrate 83 in the direction from the positive Y side toward the negative Y side.

The direction from the positive Y side toward the negative Y side corresponds to an example of "fourth connection direction" of the present disclosure.

In the embodiment, the first connection direction (the direction from the negative Y side toward the positive Y side) and the second connection direction (the direction from the positive Y side toward the negative Y side) form an angle of 180°. However, the present disclosure is not limited to this. The first connection direction and the second connection direction may form an angle of less than 180° or an angle of greater than 180°.

In the embodiment, the third connection direction (the direction from the negative Y side toward the positive Y side) and the fourth connection direction (the direction from the positive Y side toward the negative Y side) form an angle of 180°. However, the present disclosure is not limited to this. The third connection direction and the fourth connection direction may form an angle of less than 180° or an angle of greater than 180°.

In the embodiment, the first connection direction (the direction from the negative Y side toward the positive Y side) and the third connection direction (the direction from the negative Y side toward the positive Y side) form an angle of 0°. However, the present disclosure is not limited to this. The first connection direction and the third connection direction may form an angle of less than 0° or an angle of greater than 0°.

In the embodiment, the second connection direction (the direction from the positive Y side toward the negative Y side) and the fourth connection direction (the direction from the positive Y side toward the negative Y side) form an angle of 0°. However, the present disclosure is not limited to this. The second connection direction and the fourth connection direction may form an angle of less than 0° or an angle of greater than 0°.

### Effects

The region 121 is not adjacent to the region 122. Therefore, the balun 19 disposed in the region 121 is disposed so as to be separate at a distance from the balun 19 disposed in the region 121.

Thus, the electronic circuit module 1A may suppress occurrence of interference between a signal from the balun 19 and a signal from the balun 20. Therefore, the electronic circuit module 1A achieves improvement of high-frequency characteristics.

The semiconductor substrate 82 is adjacent to the region 121. Therefore, the electronic circuit module 1A may have short lengths of the wiring line 111 and the wiring line 112 between the semiconductor substrate 82 and the primary winding 41 of the balun 19.

Thus, the electronic circuit module 1A may suppress occurrence of a path loss of a radio-frequency signal flowing between the semiconductor substrate 82 and the primary winding 41. Therefore, the electronic circuit module 1A achieves improvement of high-frequency characteristics.

The semiconductor substrate 82 is adjacent to the region 122. Therefore, the electronic circuit module 1A may have short lengths of the wiring line 113 and the wiring line 114 between the semiconductor substrate 82 and the primary winding 43 of balun 20.

Thus, the electronic circuit module 1A may suppress occurrence of a path loss of a radio-frequency signal flowing between the semiconductor substrate 82 and the primary winding 43. Therefore, the electronic circuit module 1A achieves improvement of high-frequency characteristics.

The semiconductor substrate 83 is adjacent to the region 121. Therefore, the electronic circuit module 1A may have a short length of the wiring line 115 between the semiconductor substrate 83 and the secondary winding 42 of the balun 19.

Thus, the electronic circuit module 1A may suppress occurrence of a path loss of a radio-frequency signal flowing between the semiconductor substrate 83 and the secondary winding 42. Therefore, the electronic circuit module 1 achieves improvement of high-frequency characteristics.

The semiconductor substrate 83 is adjacent to the region 122. Therefore, the electronic circuit module 1A may have a short length of the wiring line 116 between the semiconductor substrate 83 and the secondary winding 44 of the balun 20.

Thus, the electronic circuit module 1A may suppress occurrence of a path loss of a radio-frequency signal flowing between the semiconductor substrate 83 and the secondary winding 44. Therefore, the electronic circuit module 1A achieves improvement of high-frequency characteristics.

The semiconductor substrate 82, the semiconductor substrate 83, the region 121, and the region 122 are disposed without extra space substantially in a rectangular shape as a whole.

Thus, the electronic circuit module 1A may reduce the layout area of the semiconductor substrate 82, the semiconductor substrate 83, the balun 19, and the balun 20. Therefore, the electronic circuit module 1A achieves a reduction in size and a reduction in cost. The electronic circuit module 1A achieves a reduction in size of an electronic device including the electronic circuit module 1A, and achieves a reduction in cost of the electronic device.

### Appendix

In the embodiment, the primary winding 41 of the balun 19 is formed on the first wiring layer, and the secondary winding 42 is formed on the second wiring layer. However, the present disclosure is not limited to this. Any configuration may be employed as long as the primary winding 41 and the secondary winding 42 are formed on different wiring layers. For example, the primary winding 41 may be formed on the first wiring layer, and the secondary winding 42 may be formed on a third wiring layer. Alternatively, for example, the secondary winding 42 may be formed on the first wiring layer, and the primary winding 41 may be formed on the second wiring layer. The same is true for the balun 20.

In the embodiment, each of the primary winding 41 and the secondary winding 42 is formed on a corresponding single wiring layer. However, the present disclosure is not limited to this. Each of the primary winding 41 and the secondary winding 42 may have multiple windings which are formed on multiple wiring layers and which are electrically connected to one another through vias. The same is true for the primary winding 43 and the secondary winding 44.

The bias circuits 201 to 204 and the control circuit 205 may be included in the electronic circuit module 1. For example, the bias circuits 201 to 204 and the control circuit 205 may be included in the semiconductor substrate 82 or the semiconductor substrate 83. Alternatively, for example, the bias circuits 201 to 204 and the control circuit 205 may be formed on a third semiconductor substrate which is mounted above or on the board 81.

The embodiments described above are made to facilitate understanding of the present disclosure, not to limit interpretation of the present disclosure. The present disclosure may be changed/improved without departing from the gist thereof, and its equivalents are also included in the present disclosure.

What is claimed is:

1. An electronic circuit module comprising:
a main board;
a first semiconductor substrate disposed above the main board and having a first side and a second side different from the first side;
a second semiconductor substrate disposed above the main board and having a third side and a fourth side different from the third side;
a first balun disposed in a first region of the main board, the first region being adjacent to the first side of the first semiconductor substrate and being adjacent to the third side of the second semiconductor substrate; and
a second balun disposed in a second region of the main board, the second region being adjacent to the second side of the first semiconductor substrate and being adjacent to the fourth side of the second semiconductor substrate.

2. The electronic circuit module according to claim 1,
wherein the first side and the second side of the first semiconductor substrate are adjacent to each other, and
wherein the third side and the fourth side of the second semiconductor substrate are adjacent to each other.

3. The electronic circuit module according to claim 1,
wherein the first side and the second side of the first semiconductor substrate are continuous at an angle, and
wherein the third side and the fourth side of the second semiconductor substrate are continuous at an angle.

4. The electronic circuit module according to claim 1,
wherein the first side and the second side of the first semiconductor substrate are opposite to each other, and
wherein the third side and the fourth side of the second semiconductor substrate are opposite to each other.

5. An electronic circuit module comprising:
a main board;
a first semiconductor substrate disposed above the main board;
a second semiconductor substrate disposed above the main board;
a first balun disposed in the main board; and
a second balun disposed in the main board,
wherein the first balun is connected to the first semiconductor substrate in a first connection direction,
wherein the second balun is connected to the first semiconductor substrate in a second connection direction different from the first connection direction,
wherein the first balun is connected to the second semiconductor substrate in a third connection direction, and
wherein the second balun is connected to the second semiconductor substrate in a fourth connection direction different from the third connection direction.

6. The electronic circuit module according to claim 5,
wherein the first connection direction and the second connection direction form an angle of 90°, and
wherein the third connection direction and the fourth connection direction form an angle of 90°.

7. The electronic circuit module according to claim 5,
wherein the first connection direction and the third connection direction form an angle of 90°, and
wherein the second connection direction and the fourth connection direction form an angle of 90°.

8. The electronic circuit module according to claim 5,
wherein the first connection direction and the second connection direction form an angle of 180°, and
wherein the third connection direction and the fourth connection direction form an angle of 180°.

9. The electronic circuit module according to claim 5,
wherein the first connection direction and the third connection direction form an angle of 0°, and
wherein the second connection direction and the fourth connection direction form an angle of 0°.

10. The electronic circuit module according to claim 2,
wherein the first side and the second side of the first semiconductor substrate are continuous at an angle, and
wherein the third side and the fourth side of the second semiconductor substrate are continuous at an angle.

11. The electronic circuit module according to claim 6,
wherein the first connection direction and the third connection direction form an angle of 90°, and
wherein the second connection direction and the fourth connection direction form an angle of 90°.

12. The electronic circuit module according to claim 8,
wherein the first connection direction and the third connection direction form an angle of 0°, and
wherein the second connection direction and the fourth connection direction form an angle of 0°.
